(19) United States
(12) Patent Application Publication
(10) Pub. No.: US 2018/0196344 A1
(43) Pub. Date: Jul. 12, 2018

(54) MASK MANAGEMENT SYSTEM AND METHOD FOR USING MASK

(71) Applicants: BOE TECHNOLOGY GROUP CO., LTD., Beijing (CN); ORDOS YUANSHENG OPTOELECTRONICS CO., LTD., Ordos, Inner Mongolia (CN)

(72) Inventors: Xiaohua ZHANG, Beijing (CN); Shaohua LIU, Beijing (CN); Zhenyu LIU, Beijing (CN); Dong YAN, Beijing (CN); Fuyi CUI, Beijing (CN)

(21) Appl. No.: 15/561,845

(22) PCT Filed: Mar. 28, 2017
(86) PCT No.: PCT/CN2017/078428

§ 371 Date: Sep. 26, 2017

(30) Foreign Application Priority Data
May 25, 2016 (CN) 201610354130.4

(51) Int. Cl. G03F 1/66; B65G 1/04

(52) U.S. Cl. CPC G03F 1/66; B65G 1/045

(57) ABSTRACT

A mask management system and a method for using a mask are provided. The mask management system includes: a mask feeding module, configured to provide at least one mask group, each of the at least one mask group including one cassette and a plurality of masks placed in the cassette; a mask detecting and processing module, configured to detect the plurality of masks in the mask group and perform a corresponding mask processing on a mask required to be processed according to a detection result; and a mask classification module, configured to readjust a mask which is processed and qualified into the cassette of the mask group to which the mask belongs.

### TECHNICAL FIELD

At least one embodiment of the present disclosure relates to a mask management system and a method for using a mask.

### BACKGROUND

A mask is required to be used in a manufacturing process of an organic light-emitting diode (OLED) display panel. In a usual mask use process, the means of management and control of a single mask is adopted.

### SUMMARY

At least one embodiment of the present disclosure relates to a mask management system and a method for using a mask, which provide fine management and control and improve the production efficiency.

At least one embodiment of the present disclosure provides a mask management system, comprising: a mask feeding module, configured to provide at least one mask group, each of the at least one mask group including one cassette and a plurality of masks placed in the cassette; a mask detecting and processing module, configured to detect the plurality of masks in the mask group and perform a corresponding mask processing on a mask required to be processed according to a detection result; and a mask classification module, configured to readjust a mask which is processed and qualified into the cassette of the mask group to which the mask belongs.

At least one embodiment of the present disclosure provides a method for using a mask, comprising: providing at least one mask group, each of the at least one mask group including one cassette and a plurality of masks placed in the cassette; detecting the plurality of masks in the mask group, and performing a corresponding mask processing on a mask required to be processed according to a detection result; and readjusting the mask which is processed in the mask processing and qualified into the mask group to which the mask belongs.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a schematic diagram of a mask management system provided by an embodiment of the present disclosure;

FIG. 2 is a schematic diagram of a mask group provided by an embodiment of the present disclosure;

FIG. 3 is a schematic diagram of a mask detecting and processing module in a mask management system provided by an embodiment of the present disclosure;

FIG. 4 is a schematic diagram of another mask detecting and processing module in a mask management system provided by an embodiment of the present disclosure;

FIG. 5 is a schematic diagram of a mask in a mask management system provided by an embodiment of the present disclosure;

FIG. 6 is a schematic diagram of another mask detecting and processing module in a mask management system provided by an embodiment of the present disclosure;

FIG. 7 is a schematic diagram illustrating mask use and management in a mask management system provided by an embodiment of the present disclosure;

FIG. 8 is a schematic diagram illustrating a case that a cassette and masks are bonded to form a mask group in a mask management system provided by an embodiment of the present disclosure;

FIG. 9 is a schematic diagram illustrating a case that the mask management system provided by an embodiment of the present disclosure is applied in manufacturing an OLED display panel;

FIG. 10 is a schematic diagram of a mask management method provided by an embodiment of the present disclosure;

FIG. 11 is a schematic diagram illustrating a case that a mask is determined to be NG by a defect detection unit in a mask management method provided by an embodiment of the present disclosure;

FIG. 12 is a schematic diagram illustrating a case that a mask is determined to be NG by a pattern detection unit in a mask management method provided by an embodiment of the present disclosure;

FIG. 13 is a schematic diagram illustrating mask detection and processing in a mask management method provided by an embodiment of the present disclosure;

FIG. 14 is a schematic diagram of a mask management method, including temporarily storing a mask group, provided by an embodiment of the present disclosure;

FIG. 15 is a schematic diagram illustrating mask classification in a method for using a mask provided by an embodiment of the present disclosure; and

FIG. 16 is a schematic diagram of a method for using a mask provided by an embodiment of the present disclosure.

Reference numerals of the accompanying drawings:
1: mask management system; 11: mask feeding module; 12: mask detecting and processing module; 13: mask classification module; 14: mask storage module; 20: evaporation equipment; 200: evaporation chamber; 201: first evaporation unit; 202: second evaporation unit; 203: third evaporation unit; 2011-2014: evaporation chamber; 2021-2024: evaporation chamber; 2031: evaporation chamber; 100: mask group; 1001: first mask group; 1002: second mask group; 1003: third mask group; 101: cassette; 102: mask; 1021: metal wire; 121: defect detection unit; 122: mask cleaning unit; 123: mask manufacturing/repairing unit; 124: pattern detection unit; 125: scrapping unit; 001: bonded mask group; 128: cassette feeding module; 129: cassette cleaning unit.

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

Unless otherwise defined, all the technical and scientific terms used herein have the same meanings as commonly understood by one of ordinary skill in the art to which the present disclosure belongs. The terms, such as “first,” “second,” or the like, which are used in the description and the claims of the present disclosure, are not intended to indicate any sequence, amount or importance, but for distinguishing various components. The terms, such as “comprise/comprising,” “include/including,” or the like are intended to specify that the elements or the objects stated before these terms encompass the elements or the objects and equivalents thereof listed after these terms, but not preclude other elements or objects. The terms, such as “connect/connecting/connected,” “couple/coupling/coupled” or the like, are not limited to a physical connection or mechanical connection, but may include an electrical connection/coupling, directly or indirectly. The terms, “on,” “under,” or the like are only used to indicate relative position relationship, and when the position of the object which is described is changed, the relative position relationship may be changed accordingly.

The means of management and control of a single mask is relatively complex, has the risk of misusing a mask, and is unfavorable for the improvement of the production efficiency.

As illustrated in FIG. 1, an embodiment of the present disclosure provides a mask management system 1, comprises: a mask feeding module 11, a mask detecting and processing module 12 and a mask classification module 13.

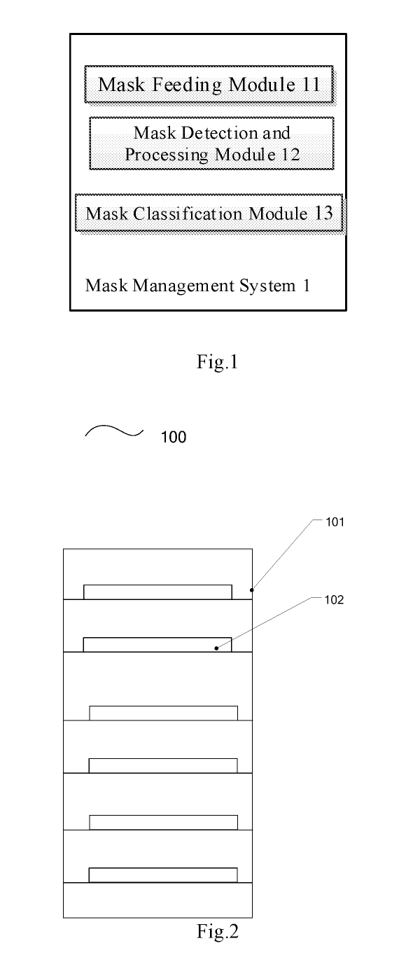

The mask feeding module 11 is configured to provide at least one mask group. As shown in FIG. 2, each mask group 100 includes a cassette 101 and a plurality of masks 102 placed in the cassette 101. It should be noted that 6 masks 102 are shown in the cassette 101 in FIG. 2, but the number of the masks 102 in the cassette 101 in the embodiment of the present disclosure is not limited thereto and may also be other numbers.

The mask detecting and processing module 12 is configured to detect the plurality of masks in the mask group, and perform a corresponding mask processing on a mask required to be processed according to a detection result.

The mask classification module 13 is configured to readjust (again feed) a mask which is processed and qualified into the cassette of the mask group to which the mask belongs.

The means of managing the mask group not only can improve the production efficiency but also is favorable for the integrity and uniformity of mask information before and after usage, not only can improve the accuracy of mask feeding but also can reduce the replacement time of the mask, and can also avoid the complexity and the risk in the management and control of a single mask.

When a mask processed by the mask detecting and processing module is determined to be not good (NG), the masks in the same group will be respectively placed in different cassettes, and the classification management of the masks may make the masks to form a complete mask group again, so that the mask group can be used. That is to say, before the mask (group) is used, a plurality of masks and one cassette form one mask group, so that the mask group can be used subsequently.

For instance, the mask group 100 may be used for manufacturing an OLED display panel. Description will be given below by taking a case that the mask group 100 is applied to the OLED display panel as an example. An evaporation of a required layer of the OLED display panel is usually performed in an evaporation equipment. For instance, the OLED display panel comprises a gate layer (a gate electrode and a gate line), a gate insulating layer, an active layer, a data layer (a data line and a source-drain electrode), a pixel electrode layer, a hole transport layer (HTL), a hole injection layer (HIL), an emission layer (EML), an electron injection layer (EIL), an electron transport layer (ETL) and a common electrode layer. The EML, for instance, includes patterns capable of emitting light of RGB colors, so that the display panel can achieve color display. The EML may also emit light of other colors. No limitation will be given here in the embodiment of the present disclosure. For instance, the HTL, the HIL, the EML, the EIL, the ETL and the common electrode layer may be formed by evaporation in the evaporation equipment. In the evaporation equipment, one mask, but not limited thereto, may be utilized in the evaporation of each layer. For instance, during the evaporation of the EML, three masks may be utilized to respectively form patterns of a red subpixel, a green subpixel and a blue subpixel, so as to emit light of RGB colors, which is not limited thereto. It should be noted that a layer structure of the OLED display panel is not limited to a case as mentioned above.

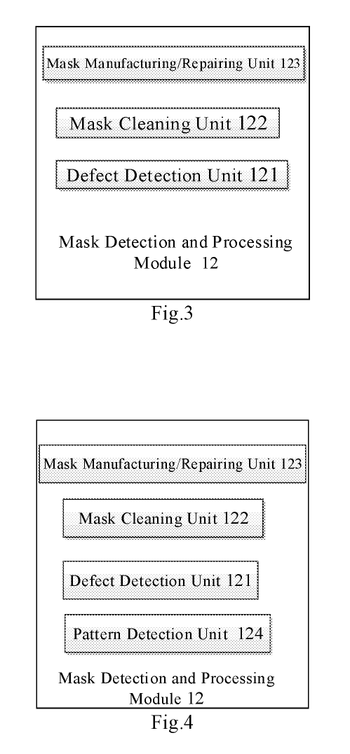

As shown in FIG. 3, in some examples, the mask detecting and processing module 12 includes:

a defect detection unit 121 configured to detect whether there is a foreign body on the detected mask;

a mask cleaning unit 122 configured to clean a mask which is detected to be defective in a detection or a mask after use; and

a mask manufacturing/repairing unit 123 configured to repair or remanufacture the mask which is detected to be defective in the detection.

The mask is needed to be performed a defect detection after use. The defect detection mainly detects the number of foreign bodies, e.g., particles, on the mask, and a cleaning is required again if the detection result is NG.

For instance, after the mask is manufactured/repaired by the mask manufacturing/repairing unit 123, the mask enters the mask cleaning unit 122 for cleaning, and enters the defect detection unit 121 for defect detection after cleaning.

In some examples, when the detected mask is determined to be NG by the defect detection unit 121 for the first time, the mask is sent into the mask cleaning unit 122 for cleaning; and when the detected mask is determined to be NG for twice in succession, the mask is sent into the mask manufacturing/repairing unit 123 for repairing or remanufacturing.

In an example, after the cleaned mask is determined to be NG in defect detection for the first time, the mask is needed to be cleaned again, and a master system will record a NG frequency of the mask to be 1. After the mask is cleaned again, the mask is needed to be defected again; and if the detection result is still NG, the master system will record the NG frequency to be 2, and a corresponding mask will be returned to the mask manufacturing/repairing unit for inspection and repairing. A case that the mask is cleaned for too many times will result in a damage of the mask and the waste of cleaning materials. When the defect detection result is OK, the master system will record the NG frequency of the corresponding mask to be zero.

As shown in FIG. 4, in some examples, the mask detecting and processing module 12 further includes: a pattern detection unit 124 configured to detect whether a pattern of the detected mask is integrated and is not damaged (in good condition). For instance, when the detected mask is determined to be NG by the pattern detection unit 124, the mask is sent into the mask manufacturing/repairing unit 123 for repairing or remanufacturing.

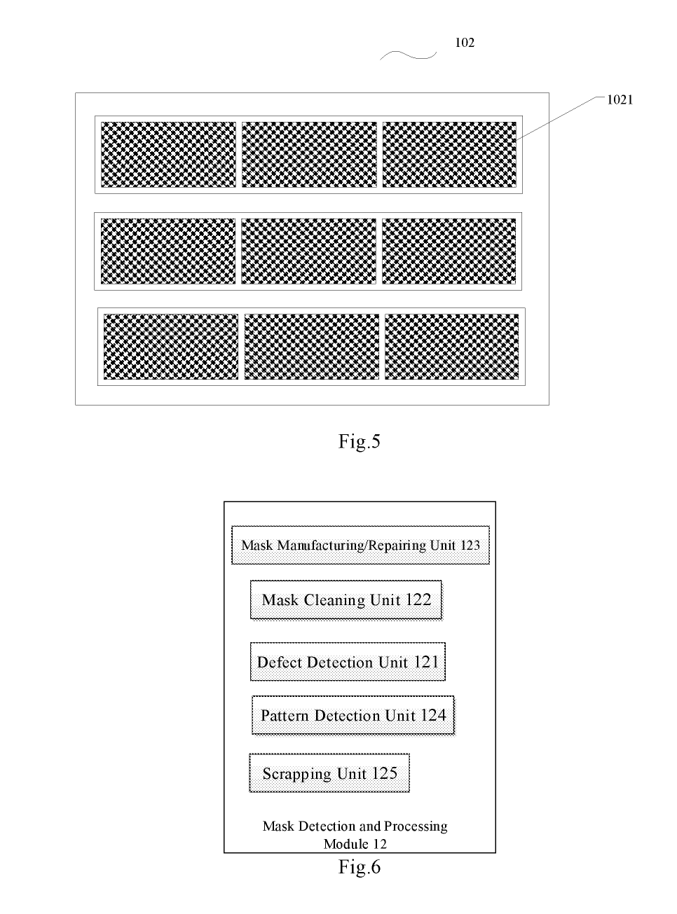

As shown in FIG. 5, metal wires 1021 crisscross to form a pattern of a mask 102. Whether the metal wires 1021 are in good condition may be detected in the pattern detection of the mask. For instance, in the manufacturing process of the mask, mesh-like metal wires may be fixed on a metal frame one by one by a tightening process. For instance, three mesh-like metal wires may be fixed on the metal frame by a tightening device to form the mask as shown in FIG. 5. It should be noted that FIG. 5 only illustratively shows one mask. The mask in the embodiment of the present disclosure is not limited to that as shown in the figure.

Pattern detection mainly detects whether the metal wires (electroplating wires) 1021 of the mask are in good condition. If the detection result is NG, repairing is required.

In one example, when the mask is subjected to a pattern detection for the first time, if the detection value is NG, the mask will return to the mask manufacturing/repairing unit for inspection and repairing, and the master system will also record the NG frequency of a corresponding mask to be 1. When the pattern detection result is OK, the master system will record the NG frequency of the mask to be zero.

For instance, if the masks processed by the mask detecting and processing module are determined to be NG in defect detection and pattern detection, the masks will be respectively placed in different cassettes.

As shown in FIG. 6, in some examples, the mask detection and processing unit 12 further includes: a scrapping unit 125 configured to scrap a mask which is unrepairable. For instance, after being scrapped, the mask may be remanufactured in the mask manufacturing/repairing unit. The remanufactured mask is subjected to subsequent processes such as cleaning, defect detection and pattern detection and forms a mask group for usage.

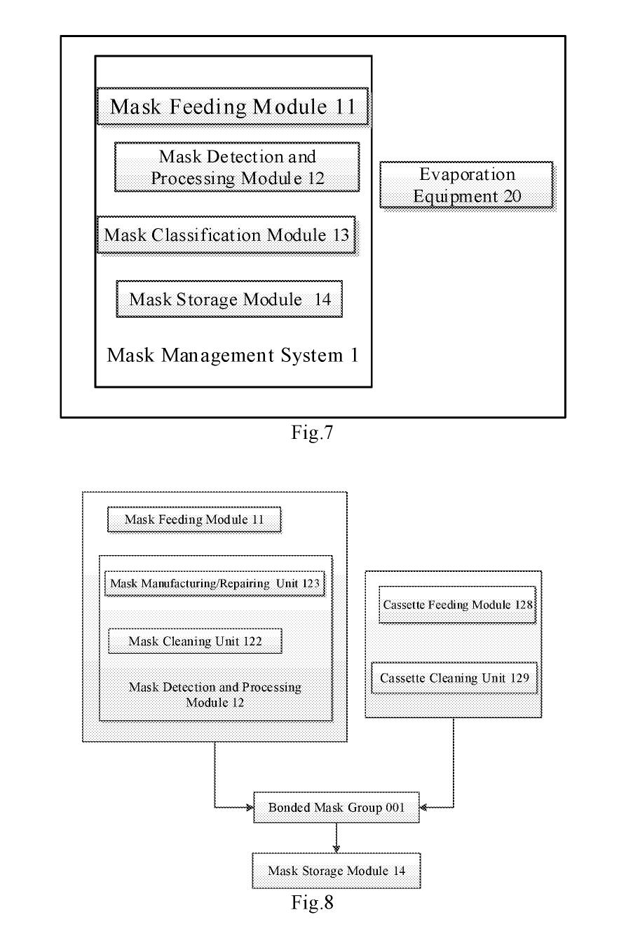

As shown in FIG. 7, the management system provided by some examples further comprises: a mask storage module 14 configured to temporarily store the mask group 100 which is detected to be qualified in a detection. If the mask group 100 is a complete mask group, the mask group may be temporarily stored into the mask storage module 14 for standby.

In an example, after the mask is fed, the mask is needed to firstly be cleaned in a cleaning unit before use. The cleaning unit may control the cleaning frequency of the mask, so as to prevent the service life of the mask from exceeding a limit value. After cleaning, defect detection is performed. If the number of particles is within a limit range, pattern detection is then performed. After the detection result is OK, the mask group will be temporarily stored into the mask storage module. When the mask is required, the mask group is taken out from the mask storage module and put into a use device for use. The used mask group is needed to be returned to the cleaning unit for the cleaning of the mask and the cassette. The process is repeated.

As shown in FIG. 7, in some examples, the mask group 100 may be used for manufacturing an OLED display panel. For instance, the mask group 100 may be applied in an evaporation equipment 20. The evaporation equipment 20, for instance, is an evaporator. For instance, the plurality of masks 102 in the mask group 100 are in the same type, or the plurality of masks 102 in the mask group 100 may include masks of at least two different types, so as to be used in different evaporation chambers of the evaporation equipment.

The management of the mask group not only can improve the production efficiency of the OLED display panel but also is favorable for the integrity and uniformity of mask information before and after evaporation. Each evaporation unit (evaporation cluster) of the evaporation equipment is provided with a plurality of chambers, and different chambers require different types of masks. When the mask is fed, the type of the masks needs to be managed, and it is appropriate to manage the masks in a group as a unit. Thus, not only the accuracy of mask feeding can be improved but also the replacement time of the mask can be reduced. Moreover, the complexity and the risk in the management and control of a single mask can be also avoided.

As shown in FIG. 8, a cassette feeding module 128 is configured to provide a cassette. The cassette is cleaned by a cassette cleaning unit 129 and bonded with masks to form a mask group. The mask group may be stored in the mask storage module 14.

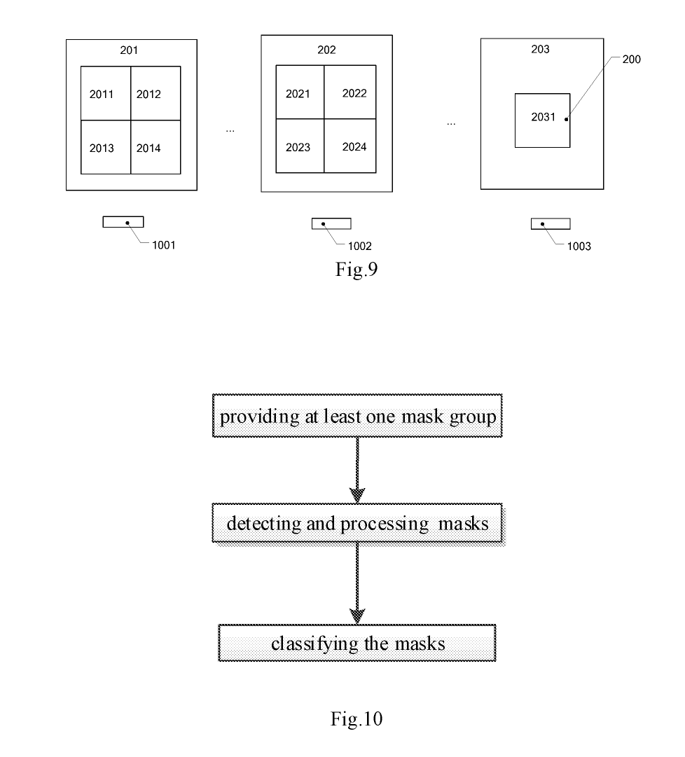

As shown in FIG. 9, the evaporation equipment 20 includes a plurality of evaporation units. Each evaporation unit is provided with a plurality of chambers 200. For instance, one layer is evaporated in each evaporation chamber. A plurality of chambers in the same evaporation unit may be used for evaporating the same layer. FIG. 9 shows first, second and third evaporation units 201-203, but not limited thereto. The first evaporation unit 201 includes four evaporation chambers 2011-2014. For instance, the evaporation chamber 2011 and the evaporation chamber 2012 may be used for evaporating a first layer; the evaporation chamber 2013 and the evaporation chamber 2014 may be used for evaporating a second layer; the first layer and the second layer respectively use a mask of one type; and masks of two types may be disposed in a first mask group 1001. For instance, three masks of the first type for evaporating the first layer and three masks of the second type for evaporating the second layer may be placed in the first mask group 1001, which is not limited thereto. For instance, the first evaporation unit 201 may be used for evaporating the HIL and the HTL, but not limited thereto. The second evaporation unit 202 includes four evaporation chambers 2021-2024, for instance, may be used for evaporating a subpixel of specific color in the EML and the ETL. A plurality of masks, which may be applied to the second evaporation unit 202, are disposed in a second mask group 1002. For instance, three masks for evaporating the subpixels of specific color and three masks for evaporating the ETL may be placed in the second mask group 1002, which is not limited thereto. It should be noted that the number of the masks disposed in the cassette of the mask group corresponding to the chamber may be determined according to the evaporation time of two layers. The number of masks corresponding to the layer with long evaporation time is small, and the number of masks corresponding to the layer with short evaporation time is large. If the evaporation time is almost the same or the time different is not large, masks of the same number may be placed. For instance, the third evaporation unit 203 includes one evaporation chamber 2031. A plurality of masks may be placed in a third mask group 1003 and used for evaporating a layer in the evaporation chamber. For instance, the evaporation chamber 2031 may be used for evaporating a cathode, but not limited thereto. It should be noted that the example is for illustrative purpose only, but not limited thereto.

In some examples, the type and the number of the plurality of masks in the cassette of the mask group are kept unchanged before the mask group is used. Thus, the cassette of one mask group and the masks disposed in the cassette may be recycled. A position of each mask disposed in the cassette is fixed, so as to avoid the misuse of the mask. When the evaporation equipment requires the masks for the production of the OLED panel, the mask group may be taken out from the mask storage module and put into the evaporation equipment for use. The mask group after evaporation use needs to be returned to the cleaning unit for the cleaning of the masks and the cassette. The process is repeated.

In one example, in the mask management system for the production of the OLED display panel, the mask manufacturing/repairing unit 123 is configured to manufacture or repair the mask which is detected to be defective in a detection; the mask cleaning unit 122 is configured to clean the mask after usage or the mask which is detected to be defective in a detection; the defect detection unit 121 is configured to detect a defect of the mask; after the mask is determined to be NG in the defect detection unit for the first time, the mask returns to the mask cleaning unit 122 for secondary cleaning; after the mask is determined to be NG for the second time in the defect detection process, the mask returns to the mask manufacturing/repairing unit 123 for again inspection; the pattern detection unit 124 is configured to detect whether the pattern of the detected mask is in good condition (integrated and is not damaged); after the mask is determined to be NG in the pattern detection unit, the mask returns to the mask manufacturing/repairing unit 123 for again inspection; the mask storage module 14 is configured to store the mask group which is detected to be qualified in a detection; the mask classification module 13 is configured to classify the masks and adjust an incomplete mask group to be a complete mask group; the complete mask group may be put into the evaporation equipment for use; and the mask returns to the mask cleaning unit for cleaning after use. The process is repeated.

For instance, in the above mask management system, the mask cleaning unit or the cassette cleaning unit is, for instance, a cleaner; the defect detection unit is, for instance, a defect detector (a particle detector); the pattern detection unit is, for instance, a pattern detector; and the mask storage module is, for instance, a storage bin, but not limited thereto.

One embodiment of the present disclosure provides a method for using a mask, which, as shown in FIG. 10, comprises:

providing at least one mask group, in which each mask group includes one cassette and a plurality of masks placed in the cassette;

detecting the masks in the mask group and performing a corresponding mask processing on a mask required to be processed according to a detection result; and

readjusting the mask which is processed in the mask processing process and qualified into the mask group where the mask is originally placed.

In the method for using a mask provided by some examples, the detection of the masks includes defect detection, so as to detect whether there are foreign bodies on the detected mask (e.g., particle detection) and then clean or repair or remanufacture a mask which is detected to be defective in a detection.

The management and control of the detection result can distinguish the masks with different detection results, so as to select a next process for the mask according to the detection result.

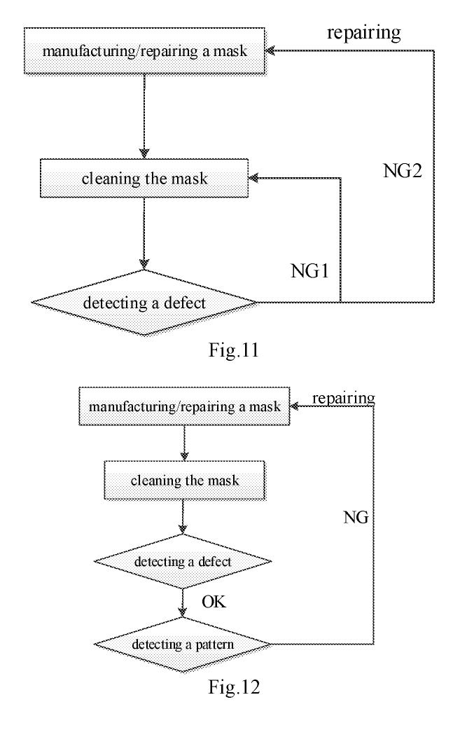

As shown in FIG. 11, in the method for using a mask provided by some examples, when the detected mask is determined to be NG for the first time, the mask needs to be cleaned again; and when the detected mask is determined to be NG for twice in succession, the mask is repaired or remanufactured.

As shown in FIG. 12, in the method for using a mask provided by some examples, a detection of the masks also includes a pattern detection, so as to detect whether a pattern of the detected mask is in good condition. For instance, when the detected mask is determined to be NG, the mask is repaired or remanufactured.

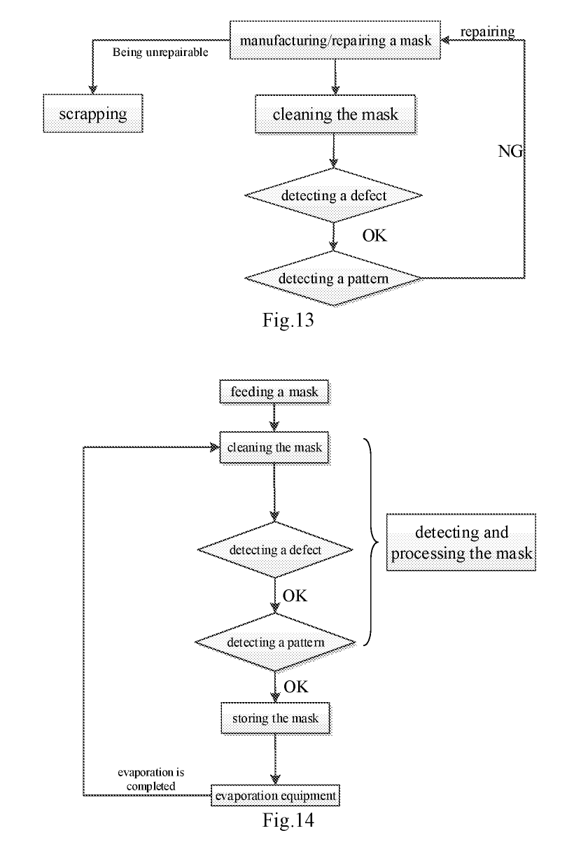

As shown in FIG. 13, in the method for using a mask provided by some examples, a mask processing further includes scrapping of the mask which is unrepairable.

As shown in FIG. 14, the method for using a mask provided by some examples further comprises: temporarily storing the mask group which is detected to be qualified in a detection. When the mask group is required, the mask group may be taken out for use from a temporary storage position (e.g., the mask storage module).

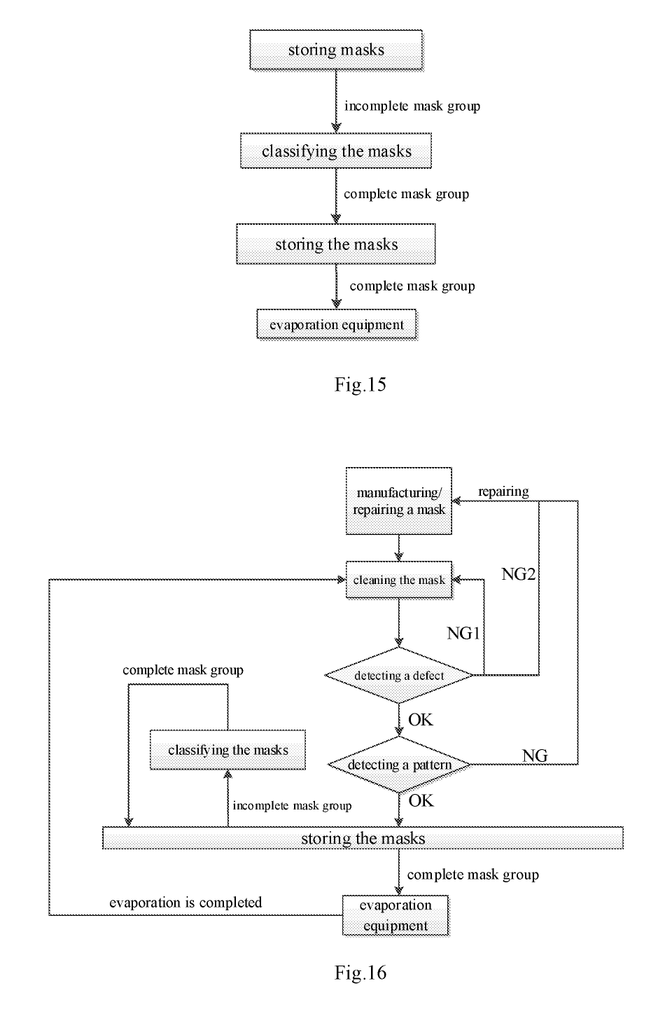

As shown in FIG. 15, if the mask group 100 is not a complete mask group, the mask group may be taken out from a mask storage position (e.g., the mask storage module 14) and sent to a defect detection position (e.g., the defect detection unit) and/or a pattern detection position (e.g., the pattern detection unit) for classification management, and the incomplete mask group may be adjusted to be a complete mask group. For instance, during classification, after being processed and qualified, the mask which has been once determined to be NG will return to the mask group corresponding to the mask, so as to form a complete mask group. The mask group after classification may be stored for standby (for instance, placed into the storage module for temporary storage and ready for use). The classification management of the masks can improve the accuracy of the mask group and prevent an improper mask from being put into the chamber of the evaporation equipment, and can also reduce the damage caused by a fact that a staff makes contact with the mask.

In the method for using a mask provided by some examples, the mask group is used for manufacturing an OLED display panel.

In the method for using a mask provided by some examples, the plurality of masks in the mask group belong to the same type, or the mask group includes masks of at least two different types, as to be used in different evaporation chambers of the evaporation equipment.

The method for using a mask provided by some examples further comprises: remaining the type and the number of the masks in the cassette of the mask group unchanged.

As shown in FIG. 16, in one example, in the mask management method for the production of the OLED display panel, a mask cleaning may be performed after mask manufacturing/repairing, and a defect detection may be performed after cleaning; after the mask is determined to be NG for the first time in the detect detection process, the mask returns to the mask cleaning process for again cleaning; after the mask is determined to be NG for twice in the defect detection process, the mask returns to the mask manufacturing/repairing process for again inspection; a pattern detection is performed after the mask is qualified in the defect detection; after the mask is determined to be NG, the mask returns to the mask manufacturing/repairing process for again inspection; the mask group may be stored after the mask is qualified in the pattern detection; incomplete masks may be subjected to mask classification; the incomplete mask group is adjusted to be a complete mask group; the complete mask group may be put into the evaporation equipment for use; and the mask may be placed into another cassette (avoiding polluting masks which are not used currently in the mask group to which the mask belongs) and returns to the mask cleaning process for cleaning after use. The process is repeated.

In the embodiment of the present disclosure, the plurality of masks 102 placed into the cassette 101 return to the original positions after processed by different units or processes. That is to say, one cassette 101 is provided with the plurality of masks 102; the position of the plurality of masks 102 in the cassette is fixed; and under a condition that a mask is scrapped, a mask may be remanufactured to replace the scrapped mask.

The effects of the mask management method provided by the embodiment of the present disclosure may correspondingly refer to the mask management system provided by the embodiment of the present disclosure. No further description will be given here. Others may also refer to each other.

It should be understood by those skilled in the art that the embodiment of the present disclosure may be a method, a device (equipment) or a computer program product. Therefore, the embodiment of the present disclosure may adopt a complete hardware embodiment, a complete software embodiment or an embodiment combining software and hardware. Moreover, the embodiment of the present disclosure may adopt a computer program product implemented on one or more computer available storage media (including but not limited to a disk memory, a CD-ROM and an optical memory) including computer available program codes.

The embodiment of the present disclosure is described according to the flow diagram and/or block diagram of the method, the device (equipment) and the computer program product provided by the embodiment of the present disclosure. It should be understood that each flow and/or block in the flow diagram and/or the block diagram and a combination of the flow and/or block in the flow diagram and/or the block diagram are implemented by a computer program instruction. The computer program instructions may be provided to a general purpose computer, a special purpose computer, an embedded processor or a processor of other programmable data processing devices to produce a machine, so that an instruction executed by the computer or the processor of other programmable data processing devices can produce a device for implementing a function specified by one flow path or a plurality of flow paths in the flow diagram or one block or a plurality of blocks in the block diagram.

The computer program instructions may also be stored in a computer-readable memory capable of guiding the computer or other programmable data processing devices to work in a particular way, so that the instruction stored in the computer-readable memory can produce a product including an instruction device. The instruction device implements a function specified by one flow path or a plurality of flow paths in the flow diagram and/or one block or a plurality of blocks in the block diagram.

The computer program instructions may also be loaded onto the computer or other programmable data processing devices, so that a series of operation steps can be executed on the computer or other programmable devices to produce computer implementable processing. Thus, the instruction executed on the computer or other programmable devices can provide a step for implementing a function specified by one flow path or a plurality of flow paths in the flow diagram and/or one block or a plurality of blocks in the block diagram.

For instance, in the embodiment of the present disclosure, the mask management system may comprise a processor, a memory and computer program instructions stored in the memory. when the computer program instructions are executed by the processor, a function specified by at least one of, for instance, the mask feeding module 11, the mask detecting and processing module 12 and the mask classification module 13 can be achieved, and moreover, for instance, all or partial functions specified by at least one of the mask feeding module 11, the mask detecting and processing module 12, the mask classification module 13, the mask storage module 14, the defect detection unit 121, the mask cleaning unit 122, the mask manufacturing/repairing unit 123, the pattern detection unit 124, the scrapping unit 125, the cassette feeding module 128 and the cassette cleaning unit 129 can be achieved.

For instance, one embodiment of the present disclosure provides a mask management system, which comprises: a processor, a memory and computer program instructions stored in the memory, when the computer program instructions are executed by the processor, the following steps are executed: providing at least one mask group, each mask group includes one cassette and a plurality of masks placed in the cassette; detecting the plurality of masks in the mask group, and performing a corresponding mask processing on a mask required to be processed according to a detection result; and readjusting the mask which is processed and qualified into the cassette of the mask group to which the mask belongs.

The following statements should be noted:

(1) The accompanying drawings involve only the structure(s) in connection with the embodiment(s) of the present disclosure, and other structure(s) can be referred to common design(s).

(2) In case of no conflict, features in one embodiment or in different embodiments can be combined.

Although detailed description has been given above to the present disclosure with general description and embodiments, it shall be apparent to those skilled in the art that some modifications or improvements may be made on the basis of the embodiments of the present disclosure. Therefore, all the modifications or improvements made without departing from the spirit of the present disclosure shall all fall within the scope of protection of the present disclosure.

The application claims priority to the Chinese patent application No. 201610354130.4, filed May 25, 2016, the disclosure of which is incorporated herein by reference as part of the application.

1. A mask management system, comprising:
a mask feeding module, configured to provide at least one mask group, each of the at least one mask group including one cassette and a plurality of masks placed in the cassette;
a mask detecting and processing module, configured to detect the plurality of masks in the mask group and perform a corresponding mask processing on a mask required to be processed according to a detection result; and
a mask classification module, configured to readjust a mask which is processed and qualified into the cassette of the mask group to which the mask belongs.

2. The management system according to claim 1, wherein the mask detecting and processing module includes:
a defect detection unit, configured to detect whether there is a foreign body on the detected mask;
a mask cleaning unit, configured to clean a mask which is detected to be defective in a defect detection or a mask after being used; and
a mask manufacturing/repairing unit, configured to repair or remanufacture the mask which is detected to be defective in the defect detection.

3. The management system according to claim 2, wherein when the detected mask is determined to be no good (NG) by the detect detection unit for the first time, the mask is sent into the mask cleaning unit for cleaning; and when the detected mask is determined to be NG for twice in succession, the mask is sent into the mask manufacturing/repairing unit for repairing or remanufacturing.

4. The management system according to claim 2, wherein the mask detecting and processing module further includes:
a pattern detection unit, configured to detect whether a pattern of the detected mask is in good condition.

5. The management system according to claim 4, wherein when the detected mask is determined to be NG by the pattern detection unit, the mask is sent into the mask manufacturing/repairing unit for repairing or remanufacturing.

6. The management system according to claim 2, wherein the mask detecting and processing module further includes:
a scrapping unit, configured to scrap a mask which is unrepairable.

7. The management system according to claim 1, further comprising:
a storage module, configured to temporarily store the mask group which is detected to be qualified.

8. The management system according to claim 7, wherein the mask group is used for manufacturing an organic light-emitting diode (OLED) display panel.

9. The management system according to claim 1, wherein the plurality of masks in the mask group are in a same type, or the plurality of masks in the mask group include masks of at least two different types, so as to be used in different evaporation chambers of an evaporation equipment.

10. The management system according to claim 9, wherein a type and a number of the plurality of masks in the cassette of the mask group are invariable before the mask group is used.

11. A method for using a mask, comprising:
providing at least one mask group, each of the at least one mask group including one cassette and a plurality of masks placed in the cassette;
detecting the plurality of masks in the mask group, and performing a corresponding mask processing on a mask required to be processed according to a detection result; and
readjusting the mask which is processed in the mask processing and qualified into the mask group to which the mask belongs.

12. The method for using the mask according to claim 11, wherein the detecting the plurality of masks includes detecting a defect, so as to detect whether there is a foreign body on the detected mask,
and then cleaning or repairing or remanufacturing a mask which is detected to be defective.

13. The method for using the mask according to claim 12, wherein when the detected mask is determined to be NG for the first time, the mask is cleaned again; and when the detected mask is determined to be NG for twice in succession, the mask is repaired or remanufactured.

14. The method for using the mask according to claim 12, wherein the detecting the plurality of masks also includes detecting a pattern, so as to detect whether a pattern of the detected mask is in good condition.

15. The method for using the mask according to claim 14, wherein when the detected mask is determined to be NG, the mask is repaired or remanufactured.

16. The method for using the mask according to claim 11, wherein the mask processing also includes scrapping a mask which is unrepairable.

17. The method for using the mask according to claim 11, further comprising: temporarily storing the mask group which is detected to be qualified.

18. The method for using the mask according to claim 11, wherein the mask group is used for manufacturing an OLED display panel.

19. The method for using the mask according to claim 11, wherein the plurality of masks in the mask group are in a same type, or the mask group includes masks of at least two different types, so as to be used in different evaporation chambers of an evaporation equipment.

20. The method for using the mask according to claim 19, further comprising: remaining a type and a number of the masks in the cassette of the mask group unchanged.
